(19) United States
(12) Patent Application Publication
(10) Pub. No.: US 2012/0061637 A1
(43) Pub. Date: Mar. 15, 2012

(54) 3-D STRUCTURED NONVOLATILE MEMORY ARRAY AND METHOD FOR FABRICATING THE SAME

(76) Inventors: Yimao Cai, Beijing (CN); Ru Huang, Beijing (CN); Shiqiang Qin, Beijing (CN); Poren Tang, Beijing (CN); LIjie Zhang, Beijing (CN); Yu Tang, Beijing (CN)

(21) Appl. No.: 13/131,601

(22) PCT Filed: Apr. 1, 2011
(86) PCT No.: PCT/CN11/72370

§ 371 Date: May 26, 2011

(30) Foreign Application Priority Data
Sep. 13, 2010 (CN) 201010279505.8

(51) Int. Cl. H01L 45/00

(52) U.S. Cl. 257/1; 438/382; 257/3; 257/E45.002

(57) ABSTRACT

The present invention relates to a field of nonvolatile memory technology in ULSI circuits manufacturing technology and discloses a 3D-structured resistive-switching memory array and a method for fabricating the same. The 3D-structured resistive-switching memory array according to the invention includes a substrate and a stack structure of bottom electrodes/isolation dielectric layers, deep trenches are etched in the stack structure of the bottom electrodes/the isolation dielectric layers; a resistive-switching material layer and a top electrode layer are deposited on sidewalls of the deep trenches, wherein the top electrodes and the bottom electrodes are crossed over each other on the sidewalls of the deep trenches with the resistive-switching material being interposed at cross-over points, each of the cross-over points forms one resistive-switching memory cell, and all of the resistive-switching memory cells form the 3D-structured resistive-switching memory array, and the 3D resistive-switching memory in the array are isolated by the isolation dielectric layers. According to the invention, the storage density of a resistive-switching memory can be improved, the process can be simplified, and the cost of the process can be reduced.

### FIELD OF THE INVENTION

The present invention refers to a field of nonvolatile memory in ULSI circuits manufacturing technology, and particularly refers to a three-dimensional-structured (3D-structured) nonvolatile memory array and a method for fabricating the same.

### BACKGROUND OF THE INVENTION

Nonvolatile memories, represented by flash memory, are widely used in various products, for example, storage devices and communication devices such as mobile phones, notebook computers, palmtop computers, and solid-state disks, etc., due to the advantages of their data-holding capability even though power supply is cut off, as well as the capability of erasing and writing data for multiple times. Nowadays, flash memory has already occupied most of the market share of the nonvolatile semiconductor memory. However, as demands for high capacity, low cost, low power consumption and high performance, etc., keep increasing in a information-based society, and as the semiconductor technology is developing at a high speed, it is difficult for the conventional flash memory technology to meet the requirements of the rapid development of the nonvolatile memory technology due to reasons of its poor scalability of fabrication process, high operation voltage, and high power consumption, etc. A resistive-switching memory achieves a function of nonvolatile storage by applying a voltage or a current to a resistive-switching material so as to change a resistance value thereof and holding a high resistance or a low resistance state after powered off. The resistive-switching memory, having advantages such as being compatible with the conventional LSI fabricating technology, excellent scalability, low operation voltage and fast operation speed, is a low cost and high performance nonvolatile memory with high capacity, which has a great potential in future applications. Meanwhile, a storage density of the nonvolatile memory can be greatly increased by employing a 3D structure, so that a cost of storage can be decreased. A 3D structure of a resistive-switching memory is usually achieved by adopting a structure of cross bars and a stack of multiple layers (as shown in FIG. 1), in which it is necessary to perform a photolithography and an etching with respect to each layer of electrodes to form the structure of cross bars, thus the number of photolithography and etching is proportional to the number of layers in the stack, and therefore, the difficulty and the cost of the fabrication process are greatly increased.

In a word, how to obtain a 3D-structured resistive-switching memory array by using a simple process is one of the problems to be solved in the nonvolatile memory technology.

### SUMMARY OF THE INVENTION

The present invention provides a 3D-structured resistive-switching memory array which is capable of increasing a storage density of a resistive-switching memory, simplifying the fabrication process and reducing the cost of the process, and a method for fabricating the same. In the 3D-structured resistive-switching memory array, a data storage layer is formed of a resistive-switching material, the resistive-switching material is disposed on sidewalls of deep trenches formed in bottom electrode metal layers and isolation dielectric layers, top electrodes and bottom electrodes are crossed over each other on the sidewalls of the deep trenches and, at cross-over points of the top electrodes and the bottom electrodes, the resistive-switching material is interposed between the top and bottom electrodes, thus the top electrodes and the bottom electrodes together with the interposed resistive-switching material form resistive-switching memory cells which are isolated by the isolation dielectric layers.

The above-mentioned objects are achieved by a technical solution shown as follows.

A 3D-structured resistive-switching memory array includes: a substrate and a stack structure of bottom electrodes/isolation dielectric layers; deep trenches etched in the stack structure of the bottom electrodes/the isolation dielectric layers; a resistive-switching material layer and a top electrode layer deposited on sidewalls of the deep trenches, wherein top electrodes and the bottom electrodes are crossed over each other on the sidewalls of the deep trenches, with the resistive-switching material layer being interposed at cross-over points, each of the cross-over points forms one resistive-switching memory cell. The resistive-switching memory cells altogether form a 3D-structure resistive-switching memory array, in which the resistive-switching memory cells are isolated by the isolation dielectric layers.

A thickness of the top electrode layer and the bottom electrode layers is preferably in a range of 50 nm-100 nm, a thickness of the isolation dielectric layers is normally in a range of 100 nm-200 nm, and a thickness of the resistive-switching material layer is in a range of 10 nm-50 nm. However, the number of layers in the stack structure of the bottom electrodes/the isolation dielectric layers depends upon the fabrication process, and thus theoretically is not limited. A depth of the deep trenches, which are etched in the stack structure of the bottom electrodes/the isolation dielectric layers, is in a range of 100 nm-200 nm.

There are no special requirements for the materials of the substrate, the isolation dielectric layers and the top and bottom electrode layers. The substrate may comprise a silicon substrate, or may comprise a quartz substrate or an organic substrate, etc., and the isolation dielectric layers may comprise a layer of any insulation material, such as aluminum oxide, silicon oxide, etc. Any metal or other conductive material, which can be grown through evaporating or sputtering, for example, metals such as Ti and Cu and compounds such as TiN, may be selected as needed to form metal films or other conductive films as the electrode layers.

A method for fabricating a 3D-structured resistive-switching memory array provided by the present invention includes the following steps:

Depositing dielectric layers and electrode material layers alternately and then performing an etching to form deep trenches; depositing a resistive-switching material layer on sidewalls of the deep trenches and etching the resistive-switching material layer; depositing a top electrode metal material, and performing a photolithography and an etching with respect to the top electrode metal material to form patterns of top electrodes, so that the 3D-structured resistive-switching memory array is formed at cross-over points formed by the top electrodes and the pre-deposited bottom electrode material layers. In particular, the isolation dielectric layers (such as silicon dioxide, silicon nitride, etc.) and the electrode metal layers (such as aluminum, copper, titanium nitride, etc.) are deposited alternately on a silicon substrate or other substrate (such as a quartz substrate, a flexible substrate), with the top-most layer being a covering dielectric layer. An etching for forming deep trenches is performed on a stack structure in which the isolation dielectric layers and the electrode material layers are alternately deposited with the isolation dielectric layer on the substrate being used as a stop layer. A resistive-switching material (such as hafnium oxide, zirconium oxide, titanium oxide, etc.) is deposited on the deep trenches, and then the resistive-switching material is etched back so that the resistive-switching material only remains on sidewalls of the deep trenches. Next, an electrode material is deposited, and then, a photolithography and an etching are performed with respect thereto so as to form patterns of top electrodes. In this way, the resistive-switching material is interposed at each of cross-over points where the top electrodes and the sidewalls of the pre-deposited electrode material cross over each other. Therefore, the 3D-structured resistive-switching memory array is formed in a vertical direction.

The method includes detailed steps shown as follows:

(1) growing or depositing an isolation dielectric layer (such as silicon dioxide, silicon nitride, etc.), which functions as an electrical isolation, on a silicon substrate or other substrate (such as a quartz substrate, a flexible substrate);

(2) depositing an electrode metallic layer on the isolation dielectric layer;

(3) performing steps (1) and (2) repeatedly to deposit a plurality of isolation dielectric layers and electrode metal layers. The total number of the layers can be controlled flexibly, with the top-most layer being an isolation dielectric layer;

(4) performing a photolithography and an etching with respect to the plurality of the isolation dielectric layers/the electrode metallic layers deposited as described until the bottom-most dielectric layer, so as to form a plurality of deep trenches, wherein sidewalls of the deep trenches comprise a stack structure of the isolation dielectric layers and the electrode metal layers;

(5) depositing a resistive-switching material layer (such as hafnium oxide, zirconium oxide, titanium oxide, etc.) by using the deep trenches as windows, and performing an etch-back process to retain the resistive-switching material layer only on the sidewalls of the deep trenches;
depositing an electrode metallic layer and then performing a photolithography and an etching with respect to the electrode metallic layer to form top electrodes, wherein the top electrodes, together with the resistive-switching material layer and the metallic layers on the sidewalls of the deep trenches, form 3D-structured resistive-switching memory devices and an array thereof.

The 3D resistive-switching device and the method for fabricating the same have advantages as follows when comparing to the prior art: firstly, comparing to the prior art in which a photolithography and an etching are needed to be performed each time when each electrode material layer is deposited, the method in which electrode material layers and dielectric material layers are firstly collectively deposited and then the photolithography and the etching are performed can effectively reduce the number of times by which the photolithography and the etching are performed, thus the number of steps of a fabrication process can be greatly reduced and a cost of the process can be decreased. Secondly, a size of the cross-over points at which the bottom electrodes and the top electrodes are crossed over each other is controlled by a deposition thickness of the bottom electrode material, therefore it is not limited by a resolution of the photolithography, and a size of the device can be further reduced effectively and the storage density can be improved.

Therefore, the 3D-structured resistive-switching memory array as described above and the method for fabricating the same are economic and effective solutions for improving the density of the resistive-switching memory.

### BRIEF DESCRIPTION OF THE DRAWINGS

The above-mentioned and other objects, features and advantages of the present invention will be more apparent with reference to the accompany drawings. Throughout the drawings, like reference numerals refer to like parts. The drawings are intended to illustrate the spirit of the present invention and are not necessarily to be scaled proportionally to actual sizes.

FIG. 1 is a schematic view of a conventional 3D-structured resistive-switching memory array, wherein “1” denotes top electrodes, “2” denotes bottom electrodes, and “3” denotes resistive-switching material.

FIG. 2 is a schematic view of a 3D-structured resistive-switching memory array according to the prevent invention, wherein “01” denotes a silicon substrate, “02” denotes bottom electrodes, “03” denotes isolation dielectric layers, “04” denotes resistive-switching material, and “05” denotes top electrodes.

FIGS. 3(a)-3(e) are schematic views illustrating a method for fabricating a 3D-structured resistive-switching memory array according to a preferred embodiment of the present invention.

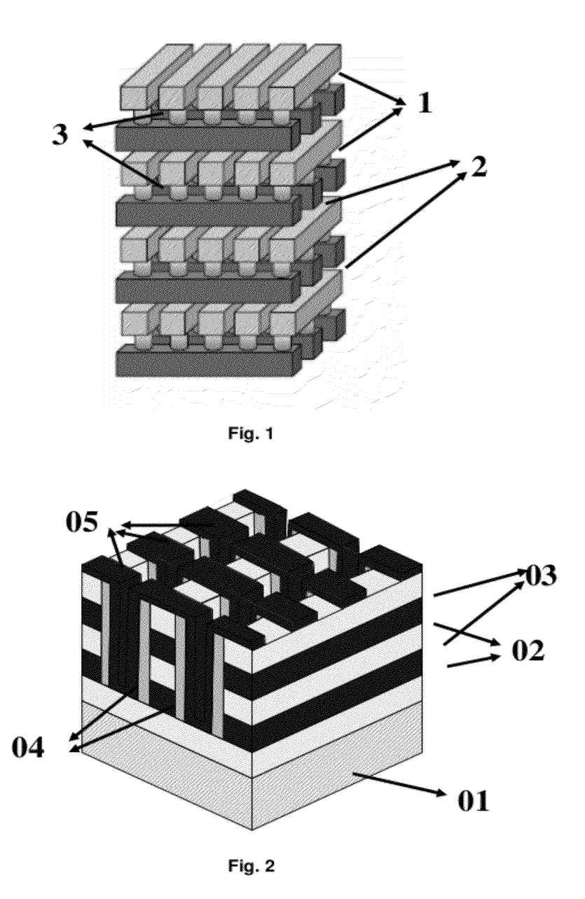

### DESCRIPTION OF SPECIFIC EMBODIMENTS

Hereinafter, embodiments of the present invention will be described in more detail with reference to the accompany drawings, so that the above-mentioned objects, features and advantages of the present invention will be more apparent.

Although many details will be described in the following description to facilitate a proper understanding of the invention, other embodiments which are different from those described herein may also be adopted in the present invention. Those skilled in the art can make similar modifications without departing from the spirit of the invention. Hence the invention is not limited to the embodiments disclosed hereinafter.

Further, the present invention is described in more detail with reference to the schematic views. In the description of the embodiments of the invention, a cross-sectional view indicating a structure of a device may not be scaled according to a normal proportion and may be enlarged partially for purpose of illustration. The illustrative views are merely examples, which are not intended to limit the scope of the invention. Moreover, a 3D spatial size with length, width and depth should be included in an actual fabrication.

As introduced in the background of the invention, the inventor has found out, through research, that if a 3D technology is applied suitably to a resistive-switching memory device, advantages of both the new storage material and the 3D integrated technology can be combined, so that problems of decrease in scalability, high operational power consumption and high operational voltage of the conventional nonvolatile memory can be solved. Moreover, a storage density of the nonvolatile memory can be further increased, and a performance of the nonvolatile memory can be improved. The storage density and the performance of the nonvolatile memory can be improved greatly if a 3D-structured resistive-switching memory array and a method for fabricating the same can be proposed by optimizing a fabrication process without increasing a complexity of the process.

Accordingly, the present invention provides an innovative 3D resistive-switching memory array and a method for fabricating the same, in which a structure of 3D resistive-switching devices can be formed by depositing dielectric layers and electrode layers alternately to form a stack, performing an photolithography and an etching with respect to the entire stack, and forming a resistive-switching material on sidewalls. Thus a storage density can be increased, the number of steps of the process can be reduced, and a cost can be decreased.

As shown in FIG. 2, a 3D resistive-switching memory array according to the present invention includes a silicon substrate 01, bottom electrodes 02, isolation dielectric layers 03, resistive-switching material 04, and top electrodes 05. The bottom electrodes 02 and the top electrodes 05 are crossed over each other on sidewalls of deep trenches in a stack structure of the bottom electrodes/the isolation dielectric layers, and the resistive-switching material 04 is interposed at respective cross-over points. Each of the cross-over points forms a memory cell and is isolated by the dielectric layers, and the cells altogether form a 3D resistive-switching memory array.

A method for fabricating the above-mentioned 3D resistive-switching memory array includes following steps.

Isolation dielectric layers (such as silicon dioxide, silicon nitride, etc.) and electrode metal layers (such as aluminum, copper, titanium nitride, etc.) are deposited alternately on a silicon substrate or other substrate (such as a quartz substrate, a flexible substrate), with the top-most layer being a covering dielectric layer. An etching for forming deep trenches is performed on a stack structure in which the isolation dielectric layers and the electrode material layers are alternately deposited, with the isolation dielectric layer on the substrate being used as a stop layer. Resistive-switching material (such as hafnium oxide, zirconium oxide, titanium oxide, etc.) is deposited on the deep trenches, and then the resistive-switching material is etched so that the resistive-switching material only remains on sidewalls of the deep trenches. Next, electrode material is deposited, and an photolithography and an etching are performed with respect to the electrode material to form patterns of top electrodes. In this way, the resistive-switching material is interposed at respective cross-over points of the top electrodes and the sidewalls of the electrode materials deposited previously. Therefore, a 3D resistive-switching memory array is formed in the vertical direction.

Hereafter, a preferred embodiment of the method for fabricating a 3D resistive-switching memory array according to the present invention will be described in more detail with reference to the accompanying drawings.

(1) An isolation dielectric layer (which comprises silicon dioxide in the present embodiment) having a thickness of 100 nm-200 nm, which functions as an electrical isolation, is deposited on a silicon substrate.

(2) A TiN electrode layer having a thickness of 50 nm-100 nm is deposited on the isolation dielectric layer.

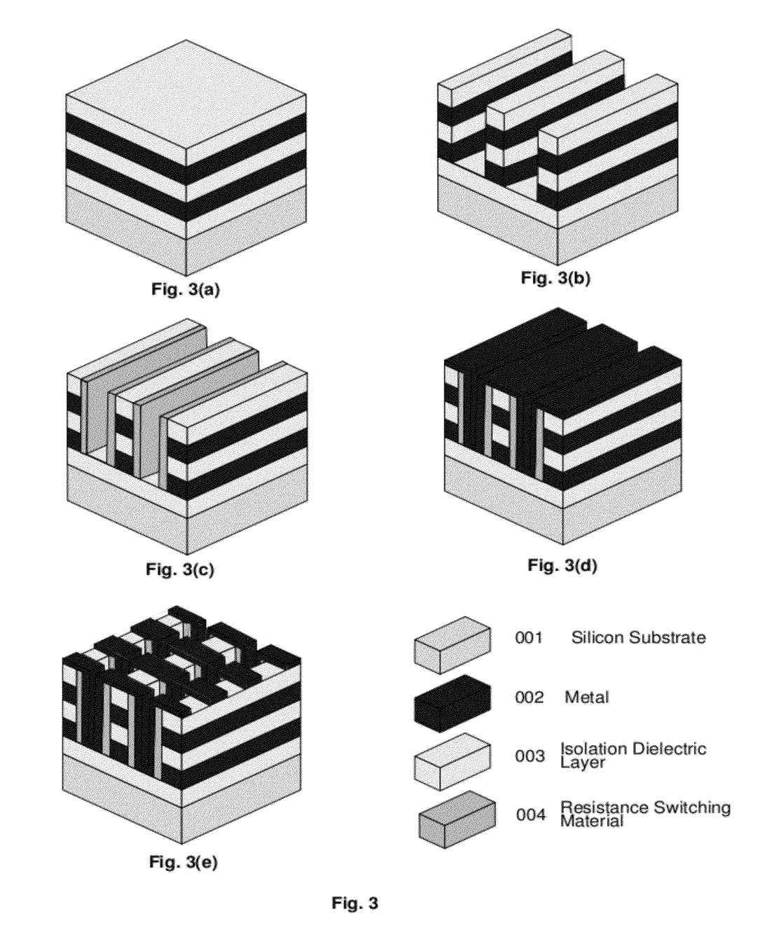

(3) The steps (1) and (2) are performed repeatedly to deposit a plurality of isolation dielectric layers and electrode metallic layers alternately, wherein the total number of the layers can be controlled flexibly, and the top-most layer is an isolation dielectric layer, as shown in FIG. 3(a).

(4) A photolithography and an etching are performed with respect to the structure of the plurality of the isolation dielectric layers/the electrode metallic layers deposited as described above until a bottom-most dielectric layer, so that a plurality of deep trenches are formed, wherein a width of each of the deep trenches is 100 nm-200 nm, and sidewalls of the deep trenches have a stack structure of isolation dielectric layers and electrode metal layers, as shown in FIG. 3(b).

(5) A resistive-switching material layer (which comprises titanium oxide in the present embodiment) having a thickness of 10 nm-50 nm is deposited by using the deep trenches as windows, and an etch-back process is performed so that only the resistive-switching material layer on the sidewalls of the deep trenches are remained, as shown in FIG. 3(c).

(6) A TiN electrode layer having a thickness of 50 nm-100 nm is deposited (FIG. 3(d)), and a photolithography and an etching are performed with respect to the TiN electrode layer to form top electrodes, wherein the top electrodes, the resistive-switching material layer and the metallic layers on the sidewalls of the deep trenches form 3D resistive-switching memory device and an array thereof, as shown in FIG. 3(e).

The foregoing description is merely a preferred embodiment of the present invention and not limitation of the present invention. Furthermore, the semiconductor device and the method for fabricating the same can be also applied to other resistive-switching memory arrays comprising a substrate, resistive-switching material, an isolation dielectric layer and electrode material, and a detailed description thereof is omitted.

While the present invention has been described above with respect to the preferred embodiment, it is not intended to limit the invention. Various changes, modifications or equivalents of the embodiments to the technical solution of the present invention can be made by those skilled in the art by using the above-mentioned methods and techniques without departing from the spirit or scope of the invention. Thus, it is intended that all such changes, modifications or equivalents of the embodiments made to the embodiments based on the technical essence without departing from the spirit or scope of the invention will fall into the scope of the invention.

What is claimed is:

1. A 3D-structured resistive-switching memory array, characterized in that, the array includes a substrate and a stack structure of bottom electrodes/isolation dielectric layers, a plurality of deep trenches are etched in the stack structure of the bottom electrodes/the isolation dielectric layers; a resistive-switching material layer and a top electrode material layer are disposed in the deep trenches, so that traverse bottom electrodes and longitudinal top electrodes are formed as crossing over each other, resistive-switching material is interposed between the bottom electrodes and the top electrodes crossing over each other, and each of crossover structures forms a resistive-switching memory cell and thus the 3D-structured resistive-switching memory array is formed.

2. A memory cell of the resistive-switching memory array according to claim 1, characterized in that the resistive-switching material layer of the memory cell is located on sidewalls of the deep trenches etched in the stack structure of the bottom electrodes/the isolation dielectric layers.

3. A method for fabricating a 3D-structured resistive-switching memory array, characterized in that, the method comprises steps of:
(1) depositing layers of dielectric material and bottom electrode material alternately on a substrate to form a stack structure of bottom electrode layers/dielectric layers;
(2) etching the stack structure of the bottom electrode layers/the dielectric layers to form a plurality of deep trenches, depositing a resistive-switching material layer on sidewalls of the deep trenches and etching the resistive-switching material layer;
(3) depositing top electrode metal material in the deep trenches and etching the top electrode metal material to form patterns of top electrodes, wherein the top electrodes and the bottom electrodes are crossed over each other on the sidewalls of the deep trenches so as to form the 3D-structured resistive-switching memory array.

4. The method for fabricating a 3D-structured resistive-switching memory array according to claim 3, characterized in that the deep trenches are formed by performing a photolithography and an etching with respect to the stack structure of the bottom electrode layers/the dielectric layers, and a bottom of each of the deep trenches is located on the first layer of the dielectric layers on the substrate.

5. The method for fabricating a 3D-structured resistive-switching memory array according to claim 3, characterized in that a thickness of the bottom electrode layers in the stack structure of the bottom electrode layers/the dielectric layers is in a range of 50 nm-100 nm.

6. The method for fabricating a 3D-structured resistive-switching memory array according to claim 3, characterized in that a thickness of the dielectric layers in the stack structure of the bottom electrode layers/the dielectric layers is in a range of 100 nm-200 nm.

7. The method for fabricating a 3D-structured resistive-switching memory array according to claim 3, characterized in that a width of the deep trenches is in a range of 100 nm-200 nm.

8. The method for fabricating a 3D-structured resistive-switching memory array according to claim 3, characterized in that a thickness of the resistive-switching material layer is in a range of 10 nm-50 nm.

9. The method for fabricating a 3D-structured resistive-switching memory array according to claim 3, characterized in that a thickness of the top electrode layer is in a range of 50 nm-100 nm.
